(19) United States
(12) Patent Application Publication
(10) Pub. No.: US 2009/0161327 A1
(43) Pub. Date: Jun. 25, 2009

(54) EXPANSION CARD

(75) Inventors: Chun-Kai Chan, Taipei (TW); Shin-Pin Lo, Taipei (TW); Li-Hsiang Liao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 12/236,522

(22) Filed: Sep. 24, 2008

(30) Foreign Application Priority Data
Dec. 21, 2007 (TW) 96149324

(51) Int. Cl. H05K 5/00

(52) U.S. Cl. 361/759

(57) ABSTRACT

An expansion card including a board is provided. The board has a chip module and a notch that is breakable. The notch divides the board into a first region and a second region, and the chip module is located in the first region.

### CROSS-REFERENCE TO RELATED APPLICATION

This application claims the priority benefit of Taiwan application serial no. 96149324, filed on Dec. 21, 2007. The entirety of the above-mentioned patent application is hereby incorporated by reference herein and made a part of specification.

### BACKGROUND OF THE INVENTION

1. Field of the Invention

The present invention generally relates to an expansion card, in particular relates to an expansion card capable of saving the fabrication cost.

2. Description of Related Art

Expansion cards are developed in the trend of small size and multifunction along with the progress of the semiconductor industry. However, desktop computers having advantages of lower prices and higher flexibility and expandability still take up a share in the server market.

For expanding the function of a desktop computer, a user usually uses the expansion card, e.g. PCI and AGP interfaces. FIG. 1 is a schematic view of a full-size expansion card and a half-size expansion card. As shown in FIG. 1, the full-size expansion card 100a and the half-size expansion card 100b are different in size. Generally speaking, the circuit layout of the full-size expansion card 100a may be effectively disposed on the entire board. However, the board of the half-size expansion card 100b has a smaller size, the circuit layout may be adjusted accordingly. Therefore, for the expansion card 100a, 100b having different sizes, the circuit layouts of the boards (not shown) may be different. Based on the above reasons, process equipments and materials for the expansion cards having two different sizes must be prepared for respectively fabricating the expansion cards of two different sizes.

### SUMMARY OF THE INVENTION

The present invention provides an expansion card that is fabricated by one set of equipment and supports two sizes, thereby saving the fabrication cost.

The present invention provides an expansion card, which includes a board. The board has a chip module and a notch that is breakable. The notch divides the board into a first region and a second region. The chip module is located in the first region.

In an embodiment of the present invention, the board has a first position fixing structure located in the first region.

In an embodiment of the present invention, the position fixing structure includes a position fixing hole or a position fixing tenon.

In an embodiment of the present invention, the board has a second position fixing structure located in the second region.

In an embodiment of the present invention, the position fixing structure includes a position fixing hole or a position fixing tenon.

In an embodiment of the present invention, the expansion card further includes a connecting interface located in the first region and electrically connected to the chip module.

In an embodiment of the present invention, the connecting interface is a golden finger.

In an embodiment of the present invention, the expansion card further includes a metal housing. The board is broken through the notch to separate the first region and the second region, and then the metal housing is installed on the board to cover the chip module.

In an embodiment of the present invention, the expansion card further includes a metal housing installed on the board and covering the notch and the chip module, so as to prevent the second region breaking under an external force and parting from the board.

A notch is formed on the board of the expansion card to divide the board into two regions. The notch of the board enables the second region to break and part from the board, so as to change the size of the expansion card. Thus, only one set of equipment is used to fabricate the expansion card, and the size of the expansion card is changed in the breaking manner, thereby saving the fabrication cost of the expansion card.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a full-size expansion card and a half-size expansion card.

FIG. 2 is a schematic view of an expansion card according to an embodiment of the present invention.

FIG. 3A is a cross-sectional view of a full-size expansion card.

FIG. 3B is a cross-sectional view of a half-size expansion card.

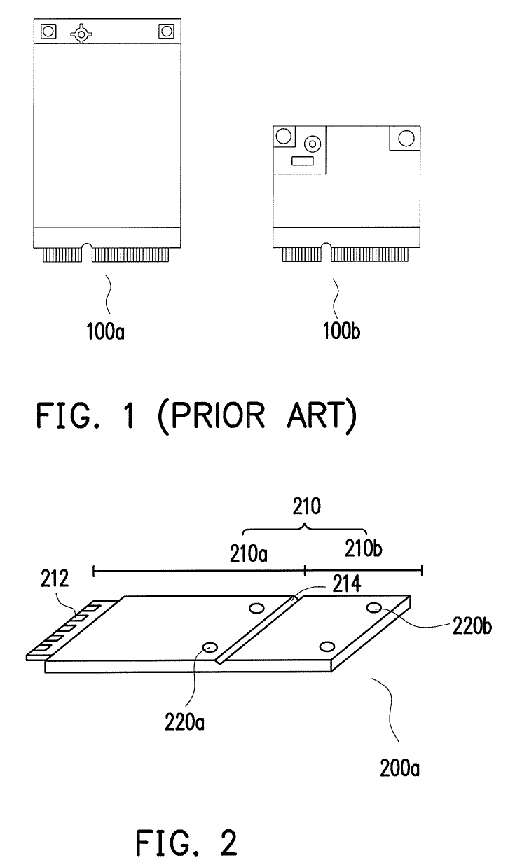

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

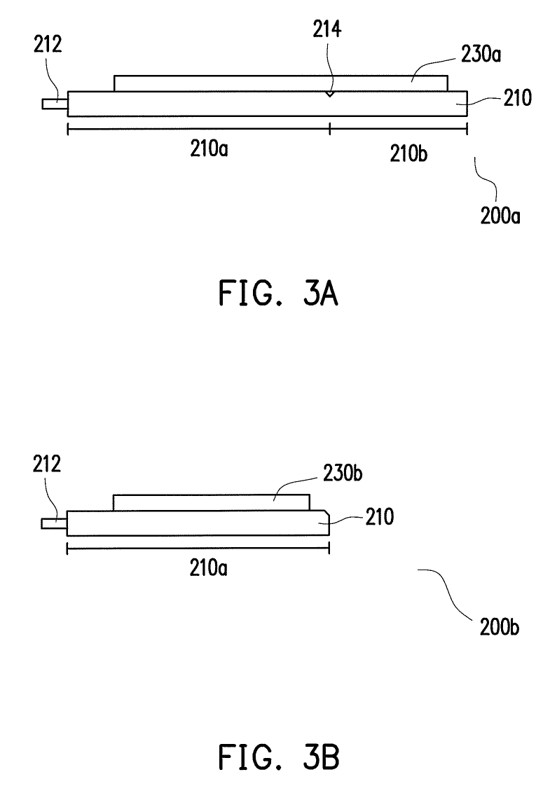

FIG. 2 is a schematic view of an expansion card according to an embodiment of the present invention. FIG. 3A is a cross-sectional view of a full-size expansion card, and FIG. 3B is a cross-sectional view of a half-size expansion card. Referring to FIGS. 2, 3A, and 3B together, the expansion card 200a includes a board 210. The board 210 has a chip module (not shown) and a notch 214 that is breakable. The notch 214 divides the board 210 into a first region 210a and a second region 210b, and the chip module is located in the first region 210a. The chip module (not shown) includes a control circuit located in the board 210 and a chip disposed on the board 210 which are used to provide an expansion function. In order to simplify the figure, the chip module is not shown in the figure. Persons of ordinary skill in the art would have the relevant knowledge about the chip module.

Particularly, the second region 210b of the expansion card 200a of this embodiment may break and part from the board 210 through the notch 214, such that the full-size expansion card 200a is changed to be a half-size expansion card 200b (as shown in FIG. 3B). Therefore, in fabrication of the expansion card of this embodiment, only one set of equipment is used to fabricate the expansion card of two different sizes, thereby saving the equipment cost.

Accordingly, the first region 210a of board 210 further includes a first position fixing structure 220a. The first position fixing structure 220a and the chip module are both located in the first region 210a, and the first position fixing structure 220a is adjacent to the notch 214. The second region 210b of the board 210 also has a second position fixing structure 220b, and the second position fixing structure 220b is relatively far away from the notch 214 and adjacent to the edge of the board 210.

In addition, the expansion card 200a further includes a connecting interface 212 located in the first region 210a and electrically connected to the chip module. The connecting interface 212 of this embodiment is a golden finger.

In detail, the chip module and the connecting interface 212 of the board 210 are all located in the first region 210a. When the user needs the full-size expansion card 200a, the expansion card 200a is disposed on the motherboard of the computer, and the motherboard has a position fixing portion corresponding to the first position fixing structure 220a and the second position fixing structure 220b. The position fixing portion interferes with the first position fixing structure 220a and the second position fixing structure 220b to enable the expansion card 200a to be stably disposed on the motherboard. In this embodiment, the first position fixing structure 220a and the second position fixing structure 220b may be a position fixing hole or a position fixing tenon depending on the practical requirements. When the first position fixing structure 220a and the second position fixing structure 220b of the expansion card 200a are the position fixing tenons, the position fixing portion on the motherboard may be position fixing holes matching the position fixing tenons. When the first position fixing structure 220a and the second position fixing structure 220b of the expansion card 200a are the position fixing holes, the position fixing portion on the motherboard may be position fixing tenons matching the position fixing holes. The position fixing tenon and position fixing hole of this embodiment are described for illustration, and persons of ordinary skill in the art would appreciate that other structures such as hooks and slots capable of achieving the interference position fixing may also be used.

In order to prevent the chip module on the board 210 from being influenced by the ambient electromagnetic waves, the expansion card 200a further includes a metal housing 230a disposed on the board 210. The metal housing 230a provides a shielding effect for preventing the expansion card 200a from the electromagnetic waves. It is worth mentioning that since the metal housing 230a may cover the first region 210a and the second region 210b of the board 210 and the notch 214 that divides the board 210 into the first and second regions 210a, 210b, the metal housing 230a may further prevent the second region 210b breaks under the external force and departs from the board 210 of the expansion card 200a through the notch 214 of the expansion card 200a.

It should be noted that when the user needs the half-size expansion card 200b, the user may break a part of the board 210 through the notch, so as to change the full-size expansion card 200a into the half-size expansion card 200b. In detail, the second region 210b of the board 210 may break and part from the board 210 by the external force applied on the notch 214 of the board 210. In this embodiment, the external force is applied in a manner that the user breaks off the second region 210b from the board 210 with hands. Alternately, the second region 210b may be cut off from the board 210 by a cutting tool, such as a knife.

Since the chip module and the connecting interface 212 are located in the first region 211a, after the second region 210b breaks off from the board 210, the half-size expansion card 200b may still maintain the complete function. Furthermore, by the use of the first position fixing structure 220a located in the first region 210a and the position fixing portion of the motherboard, the half-size expansion card 200b may be stably disposed on the motherboard. Similarly, in order to prevent the control circuit in the expansion card 200b from being influenced by the ambient electromagnetic waves, the size of the metal housing 230b installed on the board 210 of the expansion card 200b is smaller than that of the metal housing 230a. The metal housing 230b is only required to cover the first region 210a of the board 210.

In view of the above, in fabrication of the expansion card of this embodiment, only one set of fabrication equipment is used and the board material of a single size is provided to fabricate the full-size expansion card, and then the full-size expansion card is changed into the half-size expansion card by a processing method. Since the cutting tool may be directly disposed on the fabrication equipment, only one set of fabrication equipment is needed. Compared with the prior art in which the two fabrication equipments are needed for fabricating the expansion cards of two different sizes, this embodiment can save the cost of the fabrication equipment. In addition, in the supply of material, only the board of the single size is required, which is simple and convenient, and contributive to the simplification of processes.

To sum up, the expansion card of the present invention can save the cost of the fabrication equipment, and in preparation of the materials, only the board of the single size is required, which is contributive to the simplification of the fabrication processes of the expansion card.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An expansion card, comprising:
a board, comprising a chip module and a notch that is breakable, wherein the notch divides the board into a first region and a second region, and the chip module is located in the first region.

2. The expansion card according to claim 1, wherein the board comprises a first position fixing structure located in the first region.

3. The expansion card according to claim 2, wherein the first position fixing structure comprises a position fixing hole or a position fixing tenon.

4. The expansion card according to claim 2, wherein the board comprises a second position fixing structure located in the second region.

5. The expansion card according to claim 4, wherein the second position fixing structure comprises a position fixing hole or a position fixing tenon.

6. The expansion card according to claim 1, further comprising a connecting interface located in the first region and electrically connected to the chip module.

7. The expansion card according to claim 6, wherein the connecting interface is a golden finger.

8. The expansion card according to claim 1, further comprising a metal housing, wherein the board is broken through the notch to separate the first region and the second region, and then the metal housing is installed on the board to cover the chip module.

9. The expansion card according to claim 1, further comprising a metal housing installed on the board and covering the notch and the chip module, so as to prevent the second region breaking under an external force and parting from the board.
